(19) United States
(12) Patent Application Publication
(10) Pub. No.: US 2007/0222047 A1
(43) Pub. Date: Sep. 27, 2007

(54) Semiconductor package structure

(75) Inventors: Tsung-Yueh Tsai, Kaohsiung (TW); Chang-Lin Yeh, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/602,383

(22) Filed: Nov. 21, 2006

(30) Foreign Application Priority Data
Mar. 17, 2006 (TW) 95109342

(51) Int. Cl. H01L 23/02

(52) U.S. Cl. 257/678

(57) ABSTRACT

A semiconductor package structure includes a substrate, a first chip, a second chip, a wire, and an encapsulant. The substrate with a cavity has a first surface and a second surface. The cavity penetrates the first surface and the second surface. The first surface and the second surface have a first solder pad and a second solder pad respectively. The first chip having a first active surface and a first non-active surface is disposed inside the cavity. The first active surface has a first contact pad. The second chip having a second active surface and a second non-active surface is disposed on the second surface. The second non-active surface is adhered to the first non-active surface. The second active surface has a second contact pad. The wire is used for electrically connecting the second contact pad and the second solder pad. The encapsulant disposed on the substrate fills the cavity.

This application claims the benefit of Taiwan application Serial No. 95109342, filed Mar. 17, 2006, the subject matter of which is incorporated herein by reference.

### BACKGROUND OF THE INVENTION

1. Field of the Invention

The invention relates in general to a semiconductor package structure, and more particularly to a multi-chip semiconductor package structure.

2. Description of the Related Art

As more and more new electronic products emerge into the market, the functions of the electronic products have more variety as well. As for packaging technology in the electronic products, flip chip packaging is commonly used for better efficiency and smaller volume.

FIG. 1 shows a cross-sectional view of a conventional semiconductor package structure. Please referring to FIG. 1, a semiconductor package structure 100 includes a substrate 110, a first chip 130, a second chip 120, a wire 140 and an encapsulant 150. The substrate 110 has a first surface 112 and a second surface 114 opposite to the first surface 112. The first chip 130 has a first active surface 132, a first non-active surface 134 and several bumps 160. The bumps 160 are formed on the first active surface 132. An adhesive layer 126 is formed on the first non-active surface 134 of the first chip 130. The second chip 120 is disposed on the adhesive layer 126. The wire 140 is used for electrically connecting the second chip 120 and the substrate 110. The encapsulant 150 covers the first surface 112 of the substrate 110, the bumps 160, a portion of the first chip 130, a portion of the second chip 120 and the wire 140. Moreover, the semiconductor package structure 100 further includes solder balls 170 formed on the first surface 112 of the substrate 110, for being electrically connected to a printed circuit board (not shown in FIG. 1).

In the above semiconductor package structure 100, the first chip 130 is mounted through flip chip bonding to electrically connect the bumps 160 and the substrate 110. Therefore, before the encapsulant 150 is filled, the bumps 160 have to be formed on the first chip 130 first and then reflowed. After the encapsulant 150 is filled, the solder balls 170 are formed on the substrate 110 and then reflowed as well. Besides, the semiconductor package structure 100 is thick and occupies considerable space. Therefore, it is an important and unsolved problem to reduce the thickness of the semiconductor package structure and simplify the manufacturing process.

### SUMMARY OF THE INVENTION

It is therefore an object of the invention to provide a structure semiconductor package. A cavity is formed in a substrate to place a first chip, and a second chip is disposed over the first chip. As a result, the manufacturing process is simplified, and the thickness of the semiconductor package structure is reduced.

The invention achieves the above-identified object by providing a semiconductor package structure including a substrate, a first chip, a second chip, a wire and an encapsulant. The substrate with a cavity has a first surface and a second surface opposite to the first surface. The cavity penetrates the first surface and the second surface. The first surface and the second surface have a first solder pad and a second solder pad respectively. The first solder pad is electrically connected to the second solder pad. The first chip is disposed inside the cavity. The first chip has a first active surface and a first non-active surface. The first non-active surface is above the second surface. The first active surface has a first contact pad. The second chip disposed over the second surface has a second active surface and a second non-active surface. The second non-active surface is opposite to the second active surface and is adhered to the first non-active surface. The second active surface has a second contact pad. The wire is disposed between the second chip and the substrate for electrically connecting to the second contact pad and the second solder pad. The encapsulant is disposed on the substrate and fills the cavity. The encapsulant covers a portion of the first chip, the second chip, the second contact pad, the wire, the second solder pad and the second surface. Also, the encapsulant exposes the first active surface, the first surface, the first contact pad and the first solder pad.

The invention achieves the above-identified object by providing a manufacturing method of a semiconductor package structure. First, a substrate with a cavity is provided. The substrate has a first surface and a second surface opposite to the first surface. The cavity penetrates the first surface and the second surface. The first surface and the second surface have a first solder pad and a second solder pad respectively. The first solder pad is electrically connected to the second solder pad. Next, a tape is adhered to the first surface to cover an opening of the cavity. Then, a first chip is adhered insider the cavity. The first chip has a first active surface and a first non-active surface opposite to the first active surface. The first active surface having a first contact pad is adhered to the tape. The first non-active surface is above the second surface. Afterwards, a second chip is adhered to the first non-active surface. The second chip has a second active surface and a second non-active surface opposite to the second active surface. The second active surface has a second contact pad. The second non-active surface is adhered to the first non-active surface. Later, a wire is formed between the second chip and the substrate to electrically connect the second contact pad and the second solder pad. Subsequently, an encapsulant is formed to fill the cavity and cover a portion of the first chip, the second chip, the second contact pad, the wire, the second solder pad and the second surface. Thereon, the tape is removed to expose the first active surface, the first surface, the first contact pad and the first solder pad.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view of a conventional semiconductor package structure;

FIG. 2A is a cross-sectional view of a semiconductor package structure according to a first preferred embodiment of the invention;

FIG. 2B is a cross-sectional view of a semiconductor package structure according to a second preferred embodiment of the invention;

FIG. 2C is a cross-sectional view of a semiconductor package structure according to a third preferred embodiment of the invention;

FIG. 3 shows a flow chart of a manufacturing method of a semiconductor package structure according to the preferred embodiments of the invention;

FIG. 4A˜4G illustrate cross-sectional views of the manufacturing method of the semiconductor package structure according to the preferred embodiments of the invention.

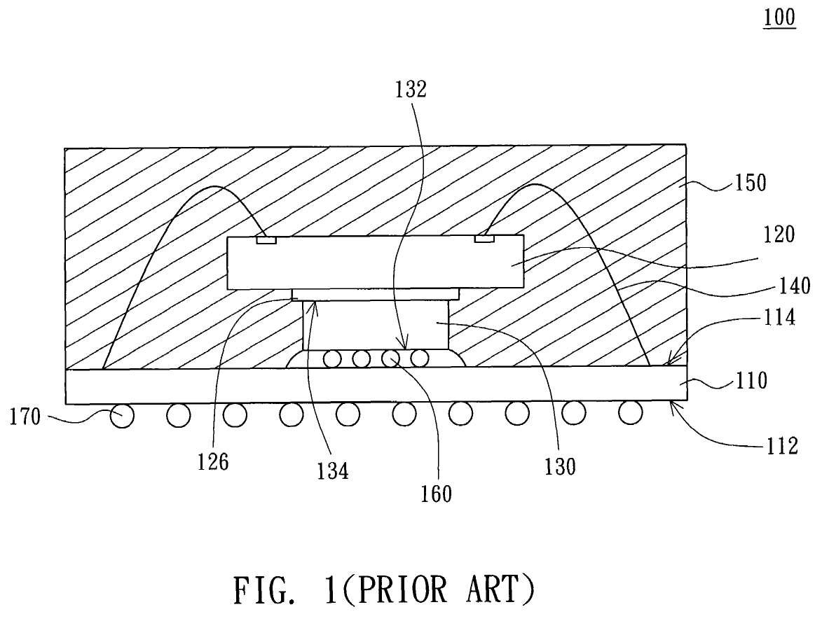

### DETAILED DESCRIPTION OF THE INVENTION

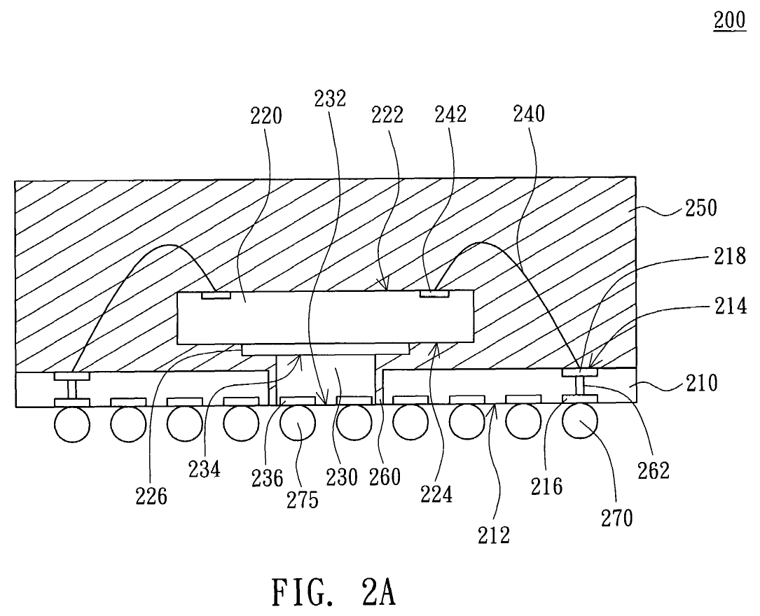

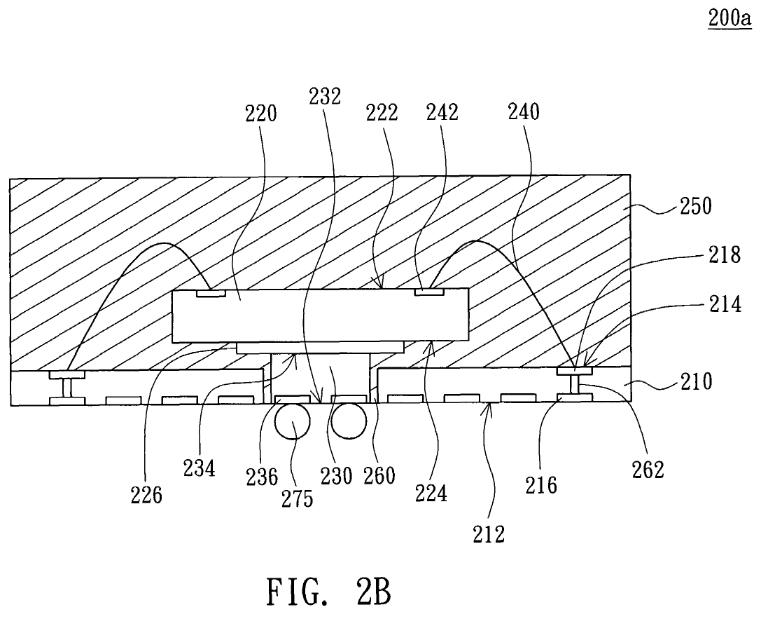

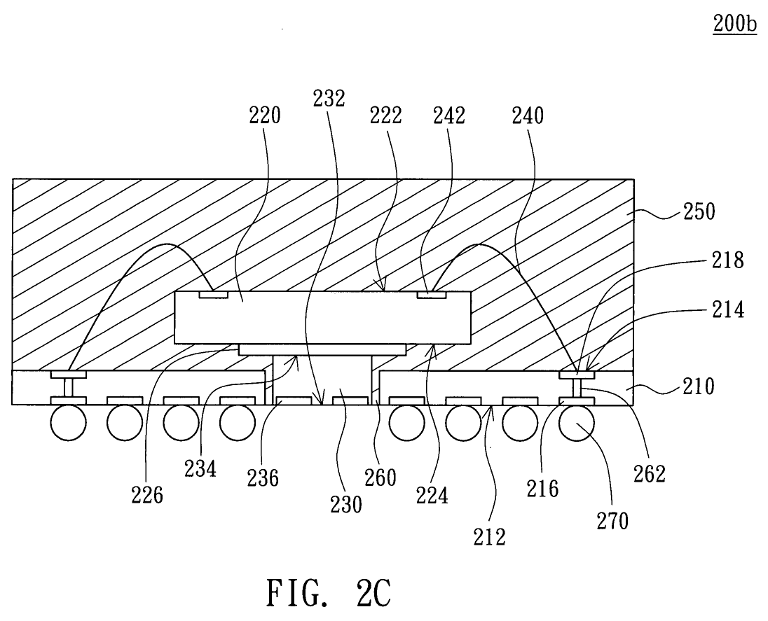

Please referring to FIG. 2A, a cross-sectional view of a semiconductor package structure according to a first preferred embodiment of the invention is illustrated in FIG. 2A. As shown in FIG. 2A, a semiconductor package structure 200 includes a substrate 210, a first chip 230, a second chip 220, a wire 240 and an encapsulant 250. A cavity 260 is formed in the substrate 210. The substrate 210 has a first surface 212 and a second surface 214 opposite to the first surface 212. A first solder pad 216 is formed on the first surface 212, and a second solder pad 218 is formed on the second surface 214. The cavity 260 penetrates the first surface 212 and the second surface 214. The first solder pad 216 is electrically connected to the second solder pad 218 through a through hole 262. A portion of the first chip 230 is disposed inside the cavity 260. The cavity 260 is larger than or has the same size as the first chip 230. The first chip 230 has a first active surface 232 and a first non-active surface 234. The first non-active surface 234 is above the second surface 214. The first active surface 232 having a first contact pad 236 has the same height as the first surface 212. The second chip 220 disposed above the second surface 214 has a second active surface 222 and a second non-active surface 224 opposite to the second active surface 222. The second non-active surface 224 is adhered to the first non-active surface 234. The second active surface 222 has a second contact pad 242. The second chip 220 is larger than the first chip 230 in the present embodiment as an example. However, anyone who has ordinary skill in the field of the invention can understand that the size of the chips is not limited thereto. For example, the second chip 220 can be smaller than or has the same size as the first chip 230.

Furthermore, the wire 240 is disposed between the second chip 220 and the substrate 210 for electrically connecting the second contact pad 242 and the second solder pad 218. For example, the wire 240 is made of gold. The encapsulant 250 is disposed on the substrate 210 and fills the cavity 260. The encapsulant 250 covers a portion of the first chip 230, the second chip 220, the second contact pad 242, the wire 240, the second solder pad 218 and the second surface 214. In the semiconductor package structure 200, the cavity 260 is formed in the substrate 210 to place the first chip 230. The first active surface 232 of the first chip 230 has the same height as the first surface 212. As a result, the steps of forming the bumps of the first chip and forming the solder balls of the substrate are able to be accomplished at the same time. Therefore, the manufacturing process of the semiconductor package structure is simplified. Also, the thickness and the volume of the semiconductor package structure are reduced.

Moreover, the semiconductor package structure 200 further includes an adhesive layer 226, a first solder ball 270, a second solder ball 275 and the through hole 262. The adhesive layer 226 is formed between the first chip 230 and the second chip 220 for adhering the first non-active surface 234 and the second non-active surface 224. The first solder ball 275 is disposed on the first contact pad 236. The second solder ball 270 is disposed on the first solder pad 216. As a result, the semiconductor package structure 200 is formed as a ball grid array (BGA) package. Before the first solder ball 275 and the second solder ball 270 are formed in the semiconductor package structure 200, the semiconductor package structure 200 is formed as a land grid array (LGA) package. The first solder ball 275 and the second solder ball 270 are used for being electrically connected to a printed circuit board (not shown in FIG. 2A). As a result, the first chip 230 and the second chip 220 are electrically connected to an outer circuit. The through hole 262 is formed between the first solder pad 216 and the second solder pad 218 and penetrates the first surface 212 and the second surface 214. The through hole 262 is used for electrically connecting the first solder pad 216 and the second solder pad 218.

Please refer to FIGS. 2B˜2C at the same time. FIG. 2B is a cross-sectional view of a semiconductor package structure according to a second preferred embodiment of the invention. FIG. 2C is a cross-sectional view of a semiconductor package structure according to a third preferred embodiment of the invention. Although several first solder balls 275 and several second solder balls 270 are formed on the first contact pads 236 and the first solder pads 216 in the present embodiment, the invention is not limited thereto. For example, as shown in FIG. 2B, only the first solder ball 275 is formed on the first contact pad 236 in a semiconductor package structure 200a. Or, as shown in FIG. 2C, only the second solder ball 270 is formed on the first solder pad 216 in the semiconductor package structure 200b. The number of the solder ball is not limited in the present invention. Furthermore, a layer of solder can be formed on the first surface 212 instead of forming the first solder ball 275 and the second solder ball 270, for being electrically connected to a printed circuit board (not shown in figures).

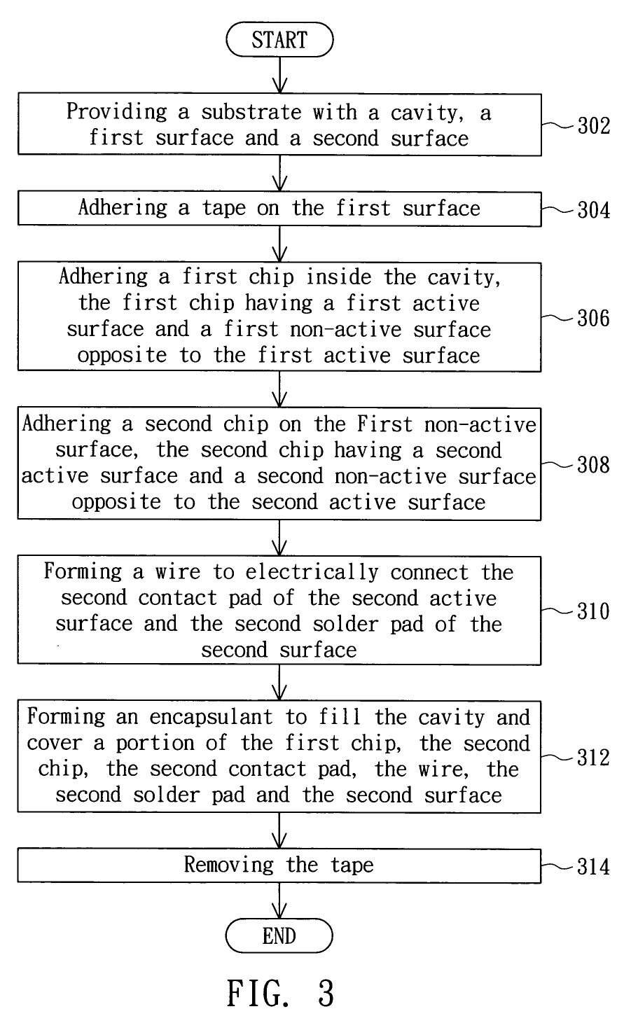

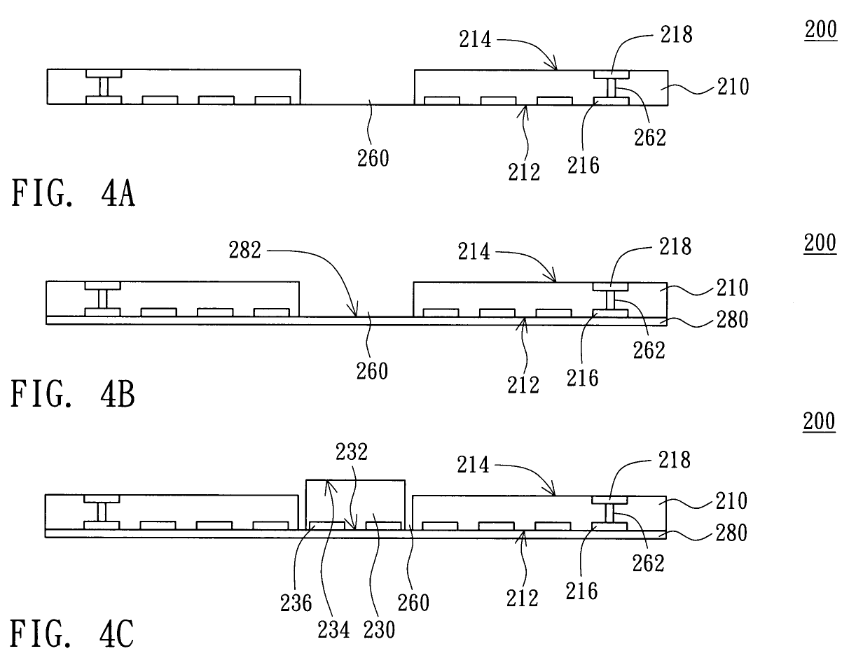

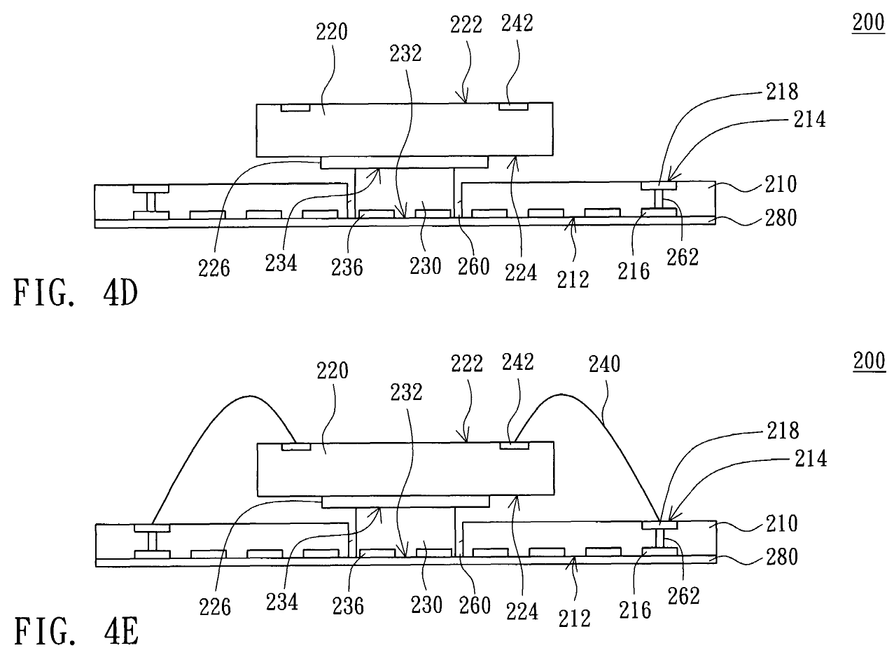

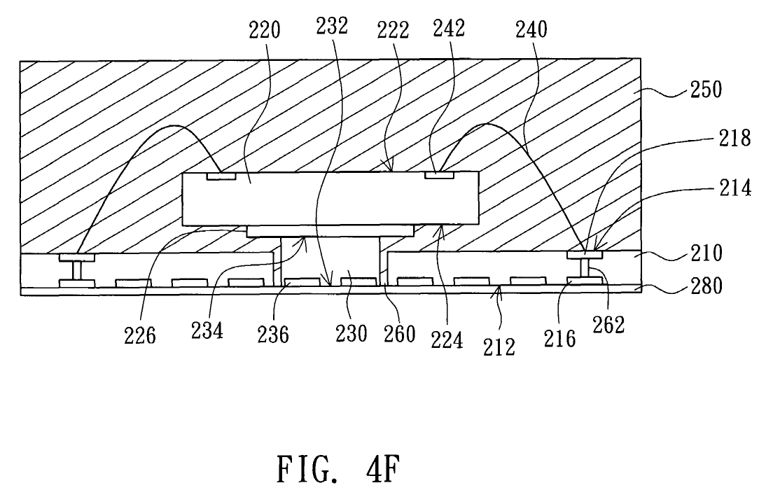

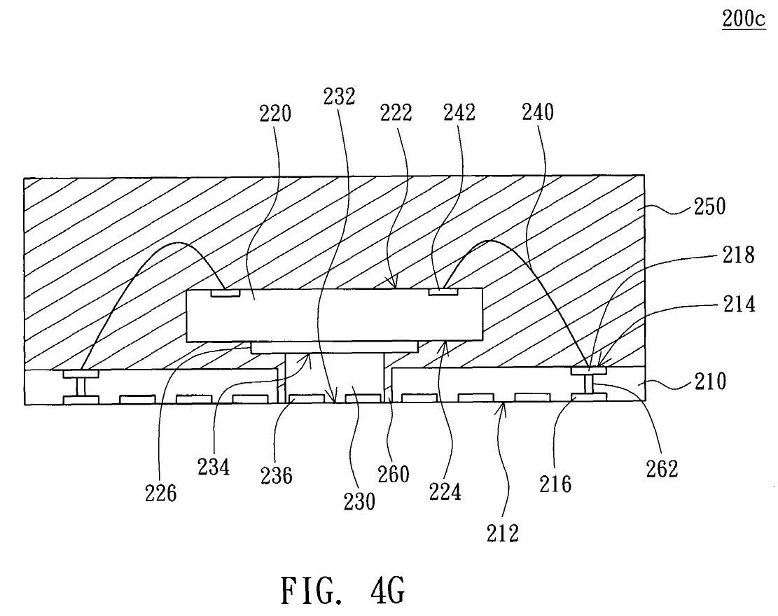

Please refer to FIG. 3 and FIGS. 4A˜4G at the same time. FIG. 3 shows a flow chart of a manufacturing method of a semiconductor package structure according to the preferred embodiments of the invention. FIG. 4A˜4G illustrate cross-sectional views of the manufacturing method of the semiconductor package structure according to the preferred embodiments of the invention. The manufacturing method of the semiconductor package structure in the present embodiment includes steps 302˜314.

First, in a step 302, the substrate 210 is provided, as shown in FIG. 4A. The substrate 210 with a cavity 216 has a first surface 212 and a second surface 214 opposite to the first surface 214. The cavity 260 penetrates the first surface 212 and the second surface 214. The first surface 212 and the second surface 214 have a first solder pad 216 and a second solder pad 218 respectively. The first solder pad 216 and the second solder pad 218 are electrically connected to each other.

Next, in a step 304, a tape 280 is adhered on the first surface 212 for covering one opening 282 of the cavity 260, as shown in FIG. 4B. For example, the tape 280 is adhered to the whole first surface 212 or just a portion of the first surface 212. The adhering method is not limited in the present invention.

Then, in a step 306, the first chip 230 is adhered inside the cavity 260, as shown in FIG. 4C. The first chip 230 has the first active surface 232 and the first non-active surface 234 opposite to the first active surface 232. The first active surface 232 including the first contact pad 236 is adhered to the tape 280. The first non-active surface 234 is above the second surface 214.

Afterwards, in a step 308, the second chip 220 is adhered to the first non-active surface 234, as shown in FIG. 4D. The second chip 220 has the second active surface 222 and the second non-active surface 224 opposite to the second active surface 222. The second active surface 222 includes the second contact pad 242. The second non-active surface 224 is adhered to the first non-active surface 234.

Subsequently, in a step 310, the wire 240 is formed between the second chip 220 and the substrate 210 for electrically connecting the second contact pad 242 and the second solder pad 218, as shown in FIG. 4E.

After, in a step 312, the encapsulant 250 is formed on the substrate 210 to fill the cavity 260 and cover a portion of the first chip 230, the second chip 220, the second contact pad 242, the wire 240, the second solder pad 218 and the second surface 214, as shown in FIG. 4F.

Then, in a step 314, the tape 280 is removed to expose the first active surface 232, the first surface 212, the first contact pad 236 and the first solder pad 216, as shown in FIG. 4G. The semiconductor package structure 200c is formed at this step and is a LGA package.

In the present embodiment, the step 308 further includes a step as shown in FIG. 4D. In FIG. 4D, the adhesive layer 226 is formed on the first non-active surface 234. Then, the adhesive layer 226 is adhered to the second non-active surface 224. Or, the adhesive layer 226 is formed on the second non-active surface 224. Then, the adhesive layer 226 is adhered to the first non-active surface 234.

In the present embodiment, the method of manufacturing the semiconductor package structure further include a step of respectively forming the first solder ball 275 and the second solder ball 270 on the first contact pad 236 and the first solder pad 216 after the step 314, as shown in FIG. 2A. Or, only the first solder ball 275 is formed on the first contact pad 236, as shown in FIG. 2B. Or, only the second solder ball 270 is formed on the first solder pad 216, as shown in FIG. 2C. Or, there can be no solder balls formed on the first contact pad 236 and the first solder pad 216. Although several first solder balls 275 and several second solder balls 270 are formed on the first contact pads 236 and the first solder pads 216 respectively in the present embodiment, anyone who has ordinary skill in the field of the invention can understand that the number of solder ball is not limited thereto.

In the semiconductor package structure and the manufacturing method thereof in the above embodiment of the invention, the cavity is formed in the substrate to place the first chip. The first active surface of the first chip is at the same height as the first surface. As a result, the steps of forming the bump of the first chip and forming the solder ball of the substrate can be accomplished at the same time. Therefore, the manufacturing process of the semiconductor package structure is simplified, and the thickness of the semiconductor package structure is reduced to save space.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package structure comprising:
a substrate with a cavity, the substrate having a first surface and a second surface opposite to the first surface, the cavity penetrating the first surface and the second surface, the first surface and the second surface comprising a first solder pad and a second solder pad respectively, the first solder pad electrically connected to the second solder pad;
a first chip disposed inside the cavity, the first chip having a first active surface and a first non-active surface opposite to the first active surface, the first non-active surface above the second surface of the substrate, the first active surface comprising a first contact pad;
a second chip disposed above the second surface of the substrate and having a second active surface and a second non-active surface opposite to the second active surface, the second non-active surface adhered to the first non-active surface, the second active surface comprising a second contact pad;
a wire disposed between the second chip and the substrate for electrically connecting the second contact pad and the second solder pad; and
an encapsulant disposed on the substrate and filling the cavity, the encapsulant covering a portion of the first chip, the second chip, the second contact pad, the wire, the second solder pad and the second surface, the encapsulant exposing the first active surface, the first surface, the first contact pad and the first solder pad.

2. The semiconductor package structure according to claim 1 further comprising:
an adhesive layer disposed between the first chip and the second chip for adhering the first non-active surface and the second non-active surface.

3. The semiconductor package structure according to claim 1 further comprising:
a first solder ball disposed on the first contact pad.

4. The semiconductor package structure according to claim 1 further comprising:
a second solder ball disposed on the first solder pad.

5. The semiconductor package structure according to claim 1, wherein the second chip is larger than the first chip.

6. The semiconductor package structure according to claim 1, wherein a through hole penetrating the first surface and the second surface is formed in the substrate for electrically connecting the first solder pad and the second solder pad.
